(19) United States
(12) Patent Application Publication
(10) Pub. No.: US 2013/0094159 A1
(43) Pub. Date: Apr. 18, 2013

(54) STORAGE DEVICE ASSEMBLY

(71) Applicants: CHEN-LU FAN, Tu-Cheng (TW); LI-PING CHEN, Tu-Cheng (TW)

(72) Inventors: CHEN-LU FAN, Tu-Cheng (TW); LI-PING CHEN, Tu-Cheng (TW)

(73) Assignee: HON HAI PRECISION INDUSTRY CO., LTD., Tu-Cheng (TW)

(21) Appl. No.: 13/525,486

(22) Filed: Jun. 18, 2012

(30) Foreign Application Priority Data
Oct. 18, 2011 (TW) 100137629

(51) Int. Cl. H05K 5/00; H05K 1/11

(52) U.S. Cl. 361/752; 361/803

(57) ABSTRACT

A storage device assembly includes a first securing tray, a first storage device received in the first securing tray, a second securing tray, a second storage device received in the second securing tray, a backplane, and a transferring board. The backplane is electronically connected to the first storage device and the transferring board, and the transferring board is electronically connected to the second storage device.

### BACKGROUND

1. Technical Field

The present disclosure relates to mounting apparatuses, and particularly, to a storage device assembly of an electronic device.

2. Description of Related Art

Many personal computers include data storage devices such as a hard disk drive (HDD), a floppy disk drive, and a compact disc-read only memory (CD-ROM) drive. The data storage devices may include a first data storage device named Serial Attached SCSI (SAS) and a second data storage device named Serial Advanced Technology Attachment (SATA). A controller of the first data storage device can control the second data storage device. However, a controller of the second data storage device cannot control the first data storage device. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a storage device assembly in accordance with an embodiment.

FIG. 2 is similar to FIG. 1, but viewed from another aspect.

FIG. 3 is an isometric view of a transferring board of the storage device assembly of FIG. 1.

FIG. 4 is similar to FIG. 3, but viewed from another aspect.

FIG. 5 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

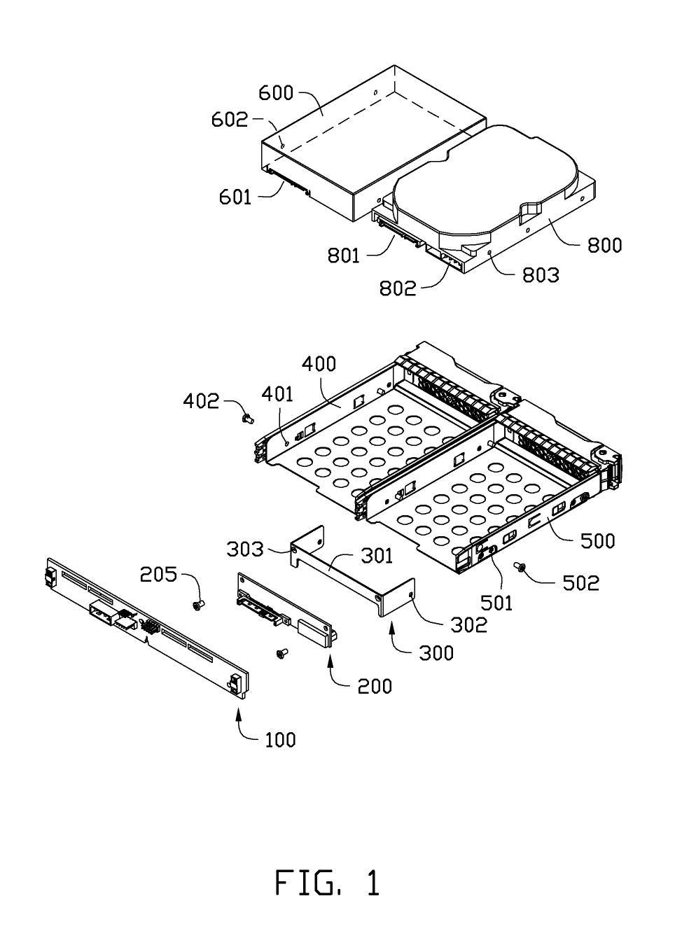

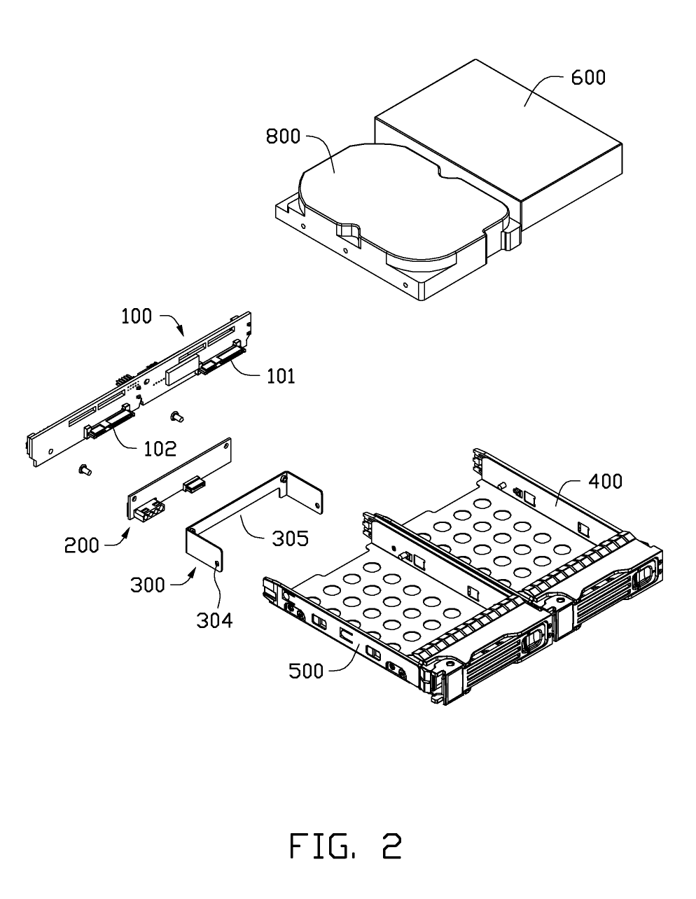

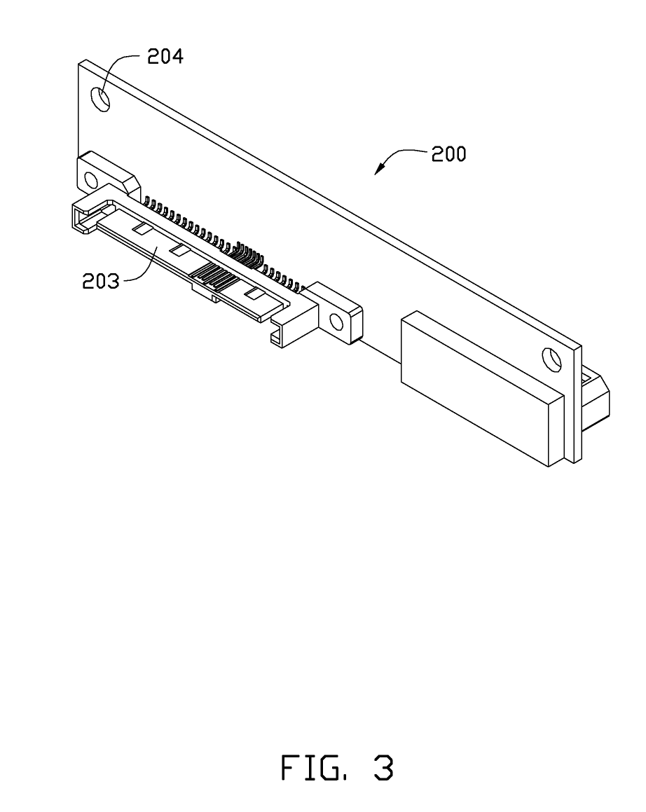

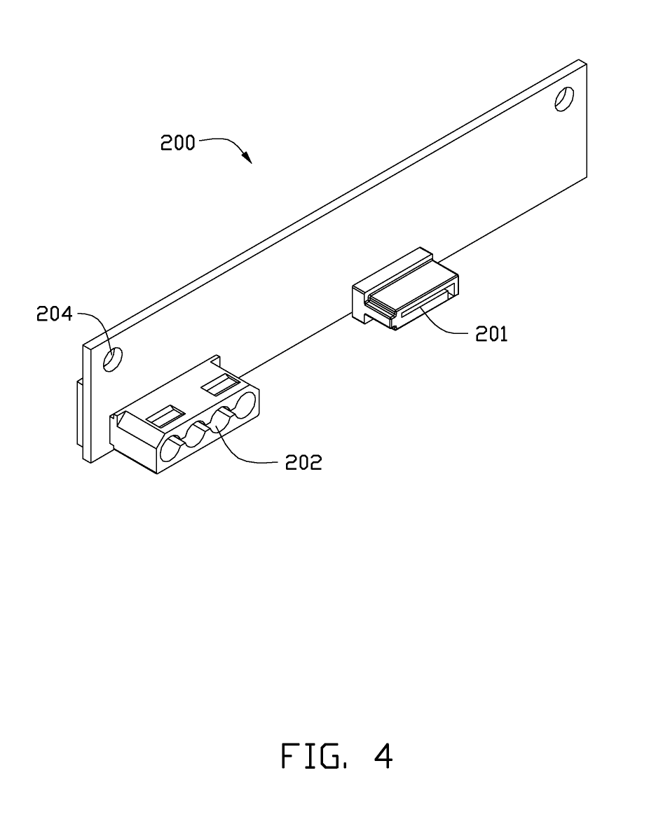

Referring to FIGS. 1-4, a storage device assembly in accordance with an embodiment includes a first securing tray 400 and a second securing tray 500. Two first through holes 401 are defined in the first securing tray 400, and two second through holes 501 are defined in the second securing tray 500. The first securing tray 400 is used to receive a first storage device 600, and the second securing tray 500 is used to receive a second storage device 800. Two first positioning holes 602 are defined in the first storage device 600, and two second positioning holes 803 are defined in the second storage device 800.

A first connector 601 is connected to the first storage device 600. The first connector 601 includes a data and power interface. A second connector 801 and a third connector 802 are connected to the second storage device 800. The second connector 801 includes a data interface, and the third connector 802 includes a power interface. In one embodiment, the first connector 601 is a Serial Advanced Technology Attachment (SATA) connector, and the second connector 801 and the third connector 802 are Serial Attached SCSI (SAS) connectors.

A backplane 100 is electronically connected to the first and second storage device 600, 800. A first backplane connector 101 and a second backplane connector 102 are electronically connected to a side of the backplane 100. The first backplane connector 101 and the second backplane connector 102 have a same configuration and may be, for example, SATA connectors. The first backplane connector 101 and the second backplane connector 102 include a data and power interface backplane

A transferring board 200 is secured to the second securing tray 500 by a mounting member 300. A first transferring board connector 201 and a second transferring board connector 202 are electronically connected to a first side of the transferring board 200, and a third transferring board connector 203 is electronically connected to a second opposite side of the transferring board 200. The first transferring board connector 201 includes a data interface, and the second transferring board connector 202 includes a power interface. The third transferring board connector 203 includes a data and power interface. In one embodiment, the third transferring board connector 203 is a SATA connector, and is electronically connected to the fifth and first transferring board connectors 201, 202. Two retaining holes 204 are defined in the transferring board 200.

The mounting member 300 includes a mounting panel 301 and two side panels 302 extending from opposite edges of the mounting panel 301. Two mounting holes 303 are defined in the mounting panel 301, and the mounting panel 300 defines an opening 305 for receiving the second and third connectors 801, 802. A fixing hole 304 is defined in each of the two side panels 302.

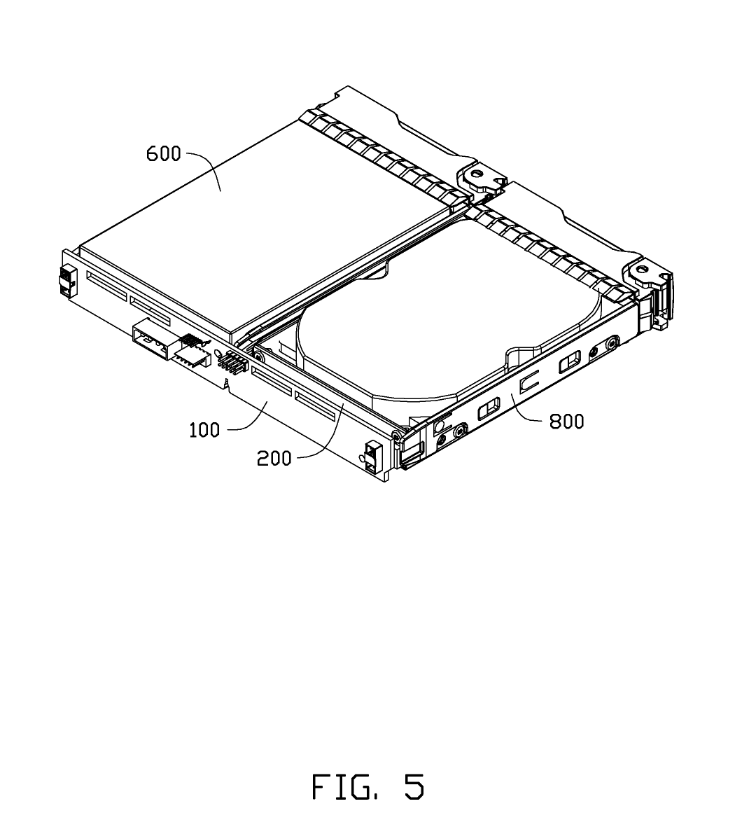

Referring to FIG. 5, in assembly, the first storage device 600 is received in the first securing tray 400, and the second storage device 800 is received in the second securing tray 500. The two first positioning holes 602 are aligned with the two first through holes 401. Two first fixing members 402 are engaged in the two first positioning holes 602 and the two first through holes 401, to secure the first storage device 600 to the first securing tray 400. The two second positioning holes 803 are aligned with the two second through holes 501. Two second fixing members 502 are engaged in the two second positioning holes 803 and the two second through holes 501, to secure the second storage device 800 to the second securing tray 500.

The transferring board 200 is attached to the mounting panel 301. The two retaining holes 204 are aligned with the two mounting holes 303. Two fasteners 205 are engaged in the two retaining holes 204 and the two mounting holes 303, to secure the transferring board 200 to the mounting member 300. The second connector 801 and the third connector 802 extend out of the opening 305 and electronically connect to the first transferring board connector 201 and the second transferring board connector 202. The first connector 601 is electronically connected to the first backplane connector 101, and the third transferring board connector 203 is electronically connected to the second backplane connector 102.

The first connector 601 is electronically connected to the first backplane connector 101. The second connector 801 and the third connector 802 are connected to the second backplane connector 102 by the transferring board 200. Therefore, data can be transmitted between the first storage device 600 and the second storage device 800.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A storage device assembly comprising:
a first storage device, and a first connector electronically connected to the first storage device; the first connector comprising a first data and power interface;
a second storage device, and a second connector and a third connector electronically connected to the second storage device; the second connector comprising a first data interface, and the third connector comprising a first power interface, and
a backplane; a first backplane connector and a second backplane connector having a configuration same as a configuration of the first backplane connector, the first backplane connector and the second backplane connector are electronically connected to the backplane; the first backplane connector comprising a second data and power interface corresponding to the first data and power interface;
a transferring board electronically connected to the second backplane connector;
wherein the first connector is electronically connected to the first backplane connector, and the second connector and the third connector are electronically connected to the transferring board.

2. The storage device assembly of claim 1, wherein a first transferring board connector and a second transferring board connector are attached to a first side of the transferring board, a third transferring board connector is attached to a second opposite side of the transferring board, the first transferring board connector comprises a second data interface corresponding to the first data interface; the second transferring board connector comprises a second power interface corresponding to the second power interface, the third transferring board connector comprises a third data and power interface corresponding to the second data and power interface; the first transferring board connector and a second transferring board connector are electronically connected to the second connector and the third connector, respectively, and the third transferring board connector is electronically connected to the second backplane connector.

3. The storage device assembly of claim 2, further comprising a second securing tray, a mounting member is attached to the second securing tray, and the transferring board is secured to the mounting member.

4. The storage device assembly of claim 3, wherein the mounting member defines an opening, and the first transferring board connector and the second transferring board connector extend through the opening.

5. The storage device assembly of claim 4, wherein the mounting member comprises a mounting panel and two side panels, each of the two side panels extending from the mounting panel, the opening is defined in the mounting panel, and each of the two side panels is attached to each opposite side of the second securing tray.

6. The storage device assembly of claim 1, wherein the first connector is a Serial Advanced Technology Attachment connector, and the second connector and the third connector are Serial Attached SCSI connectors.

7. A storage device assembly comprising:
a first securing tray; a first storage device received in the first securing tray;
a second securing tray; a second storage device received in the second securing tray;
a mounting member attached to the second securing tray;
a transferring board extending through the mounting member and electronically connected to the second storage device;
a backplane electronically connected to the first storage device and the transferring board.

8. The storage device assembly of claim 7, wherein a first connector is attached to the first storage device; the first connector comprises a first data and power interface; the backplane comprises a first backplane connector and a second backplane connector; the first backplane connector comprising a second data and power interface corresponding to the first data and power interface, the first backplane connector is electronically connected to the first connector, and the second backplane connector is electronically connected to the transferring board.

9. The storage device assembly of claim 8, wherein a second connector and a third connector are attached to the second storage device, the second connector comprising a first data interface, and the third connector comprising a first power interface, the first connector is a Serial Advanced Technology Attachment connector, and the second connector and the third connector are Serial Attached SCSI connectors.

10. The storage device assembly of claim 8, wherein a first transferring board connector and a second transferring board connector are attached a first side of the transferring board; a third transferring board connector is attached to a second side of the transferring board; the first transferring board connector comprises a second data interface corresponding to the first data interface; the second transferring board connector comprises a second power interface corresponding to the first power interface, the third transferring board connector comprises a third data and power interface corresponding to the second data and power interface; the first transferring board connector and the second transferring board connector are electronically connected to the second connector and the third connector, respectively, and the third transferring board connector is electronically connected to the second backplane connector.

11. The storage device assembly of claim 10, wherein the mounting member defines an opening, and the first transferring board connector and the second transferring board connector extend through the opening.

12. The storage device assembly of claim 11, wherein the mounting member comprises a mounting panel and two side panels, each of the two side panels extending from the mounting panel, the opening is defined in the mounting panel, and each of the two side panels is attached to each opposite side of the second securing tray.
